(19) United States
(12) Patent Application Publication
(10) Pub. No.: US 2025/0068805 A1
(43) Pub. Date: Feb. 27, 2025

(54) METHOD FOR OPTIMIZING ADJUSTMENT FACTORS OF MULTIPHASE FLOWABILITY MODELS AND COMPUTER-READABLE STORAGE MEDIA

(71) Applicant: PETRÓLEO BRASILEIRO S.A. – PETROBRAS, Rio de Janeiro (BR)

(72) Inventor: LIVIA FULCHIGNONI DE PAIVA, Rio de Janeiro (BR)

(73) Assignee: PETRÓLEO BRASILEIRO S.A. – PETROBRAS, Rio de Janeiro (BR)

(21) Appl. No.: 18/784,275

(22) Filed: Jul. 25, 2024

(30) Foreign Application Priority Data
Aug. 22, 2023 (BR) 1020230168426

(51) Int. Cl. G06F 30/28

(52) U.S. Cl. CPC G06F 30/28

(57) ABSTRACT

The present invention refers to a method to optimize adjustment factors of multiphase flowability models, comprising the steps of calculating variation in pressure and variation in temperature; defining method iteration termination criterion; setting initial values for the pressure and temperature adjustment factors; performing a first multiphase flowability simulation; updating adjustment factors; determining upper and lower limits on adjustment factors; performing a second multiphase flowability simulation; verifying if the convergence criterion has been met; and achieving optimized adjustment factors.

### FIELD OF THE INVENTION

The present invention is part of the technical field of lifting and flow technologies. In particular, the present invention refers to a method for optimizing adjustment factors of multiphase flowability models.

### BACKGROUND OF THE INVENTION

Pipeline flow simulations play a key role in Carbon Capture, Utilization and Storage (CCUS) and the oil and gas (O&G) industry. In this sense, the accurate calculation of pressure and temperature profiles from surface installation to the wellbore bottom (or vice versa) is essential for the design, operation, and optimization of injection/production systems.

The vast amount of research and development work invested in multiphase flow modeling in the last 60 years highlights the importance of the topic, as discussed in Shippen, M., Bailey, W. J., 2012. Steady-State Multiphase Flow-Past, Present, and Future, with a Perspective on Flow Assurance. Energy & Fuels 26, 4145-4157.

As a result of this effort, several multiphase flowability models have been proposed in the literature. Until the 1980s, empirical correlations to predict the pressure gradient were more common. Subsequently, mechanistic models that better describe the physical phenomena of flow gained ground, as described in Brill, J. P., Arirachakaran, S. J., 1992. State of the art in multiphase flow. Journal of Petroleum Technology 44, 538-541.

More recently, machine learning techniques have been applied to characterize multiphase flow.

However, even the best models using machine learning techniques may not be successful in matching experimental and field data, since their predictions are fundamentally uncertain. Such uncertainties can be structural, due to the inevitable approximations of reality introduced by a machine learning model, or parametric, due to the need to specify numerical values for the inputs of such a model, as discussed in Fulchignoni, L. P., Santim, C. G. S., Tartakovsky, D. M., 2023. Probabilistic forecasting of cumulative production of reservoir fluid with uncertain properties. Geoenergy Science and Engineering Journal.

Most models and simulators have been developed with limited applicability to some flow pattern and some pipeline inclination, as discussed by Choi, J., Pereyra, E., Sarica, C., Lee, H., Jang, I. S., Kang, J., 2013. Development of a fast transient simulator for gas-liquid two-phase flow in pipes. Journal of Petroleum science and engineering 102, 27-35.

Furthermore, there is a consensus in the literature that no correlation is applicable to all ranges of input data with the same degree of precision, as proven by Jahanandish, i.e., Salimifard, B., Jalalifar, H., 2011. Predicting bottom-hole pressure in vertical multiphase flowing wells using artificial neural networks. Journal of Petroleum Science and Engineering 75, 336-342.

In this regard, as an example, different multiphase flowability models can present a high variability of performance when compared to the actual field data of several oil and gas production fields, without there being a single model that offers the best results for all fields, as observed in Pucknell, J. K., Mason, J. N. E., Vervest, E. G., 1993. An Evaluation of Recent “Mechanistic” Models of Multiphase Flow for Predicting Pressure Drops in Oil and Gas Wells SPE-26682-MS.

Specifically, for a real and specific production system, the governing equations that best predict pressure, temperature, and liquid fraction profiles may vary with operating conditions, as presented in Santim, C. G. S., Fulchignoni, L. P., Rosa, E. S., Gaspari, E. F., 2020. Transient multiphase flow modeling and validation in a real production system with high CO2 content using the drift-flux model. Journal of Petroleum Science and Engineering 188, 106903.

Such structural uncertainty also applies to the smaller-scale experimental setups. As an example, it is possible to cite the uncertainty of the phase slip and frictional pressure drop models for the upward and downward two-phase flow of CO2, indicated in Hammer, M., Deng, H., Liu, L., Langsholt, M., Munkejord, S. T., 2021. Upward and downward two-phase flow of co2 in a pipe: Comparison between experimental data and model predictions. International Journal of Multiphase Flow 138, 103590.

Regarding reservoir fluid modeling, subjective choices of the optimization algorithm and initial guesses used in the regression of the equation of state can affect the final characterization of the fluid, and consequently the flow predictions, as elucidated in Fulchignoni, L. P., Tartakovsky, D. M., 2023. Uncertainty on the reservoir fluid characterization due to the equation of state regression optimization algorithm and initial guess. Geoenergy Science and Engineering Journal.

A commonly applied practice to increase the accuracy and predictability of flow models is the application of adjustment factors to the calculated parameters in order to better represent the measured field data. Such adjustment factors are, essentially, corrective multiplicative constants for one or more calculated variables.

About a decade ago, the optimization of the adjustment factors of the multiphase flow simulation model was regularly done manually, through trial and error. That is, a value for a pressure adjustment factor φP, for example, was proposed, and the influence of the change on the result of the simulation was verified. After several attempts, a value for this φP was found. The process was then repeated, this time for the temperature adjustment factor φT. Considering, for example, that the adjustment factors may be different in the production column and in the subsea line, there are then four variables/adjustment factors to be optimized: the pipe pressure adjustment factor φP^{pipe}, the pipe temperature adjustment factor φT^{pipe}, the column pressure adjustment factor φP^{column}, and the column temperature adjustment factor φT^{column}. It is worth noting that this optimization is non-linear, since the pressure profile influences the temperature profile and vice versa. Thus, manual adjustment, in addition to being costly, often does not provide a satisfactory result.

In addition, it is possible to mention the application of traditional (generic) optimization algorithms to determine the optimal adjustment factors in pipeline flow simulations. For example, as discussed by Monteiro, D. O., Duque, M. C. M. A., Chaves, G. S., Baioco, J. S., Ferreira Filho, V. J., 2018. Model Adjusting and Parameters Estimation under Uncertainties for Multiphase Flow, in: Rio Oil & Gas Expo and Conference and Chaves, G., Monteiro, D., Martins Ferreira, V. J., 2021. A Back Allocation Methodology to Estimate the Real-Time Flow and Assist Production Monitoring, in: SPE Annual Technical Conference and Exhibition, OnePetro, the pressure gradients of the well flow models are adjusted by the bisection method. While this approach is efficient for adjusting only pressure gradients, its performance can deteriorate by incorporating additional measured variables, such as temperature gradients, into the error function.

Also, Seman, L. O., Miyatake, L. K., Camponogara, E., Giuliani, C. M., Vieira, B. F., 2020. Derivative-free parameter tuning for a well multiphase flow simulator. Journal of Petroleum Science and Engineering 192, 107288 implements the direct search algorithm as discussed in Abramson, M. A., Audet, C., Dennis Jr, J. E., Digabel, S. L., 2009. OrthoMADS: a deterministic MADS instance with orthogonal directions. SIAM Journal on Optimization 20, 948-966 to calculate the adjustment factors for pressure and temperature gradients estimated by well flow models.

In this context, there is a lack of a solution that optimizes the calculation of the adjustment factors applied to pressure and temperature gradients used by multiphase flow simulators, in an efficient and effective way, being computationally accessible and providing results comparable to those obtained with more time-consuming generic optimization methods.

### STATE OF THE ART

In the state of the art, there are solutions that characterize multiphase flow, as will be discussed below.

Document US2013035919A1 describes a system for calibrating models of production and injection wells for a reservoir, including well data import and processing, which includes pressure, volume, and temperature data; validation of vertical flow correlation, comparing predicted well performance with actual measured well performance; where gravity and friction correction factors are applied so that the downhole flow pressure predicted by the correlation at the gauge depth matches the measured value. In contrast, the present invention uses multiplicative adjustment factors in the pressure and temperature gradients of multiphase flowability models.

The paper Monteiro, Danielle de Oliveira, Estimação de parametros para modelos de escoamento multifásico sob incertezas (http://hdl.handle.net/11422/12195), addresses a model for automatic adjustment of multiphase flowability models that takes into account a history of production tests and the uncertainties associated with production variables. This document considers only the pressures measured for the calibration of the multiphase flow model, considering a history of production tests and their uncertainties. However, the present invention considers the production test variables as deterministic, disregarding the associated uncertainties. In addition, the present invention considers measured values of pressure and temperature to adjust pressure and temperature gradients.

### BRIEF DESCRIPTION OF THE INVENTION

The present invention defines, according to a preferential embodiment, a method to optimize adjustment factors of multiphase flowability models, comprising the steps of:
calculate the pressure change (ΔP) in a well (ΔP^{well}) and in a pipe (ΔP^{pipe}); and the variation in temperature (ΔT) in a well (ΔT^{well}) and in a pipe (ΔT^{pipe}), based on pressure and temperature values measured in the well and in the pipe, based on:

$$\begin{matrix}Δ {P}^{well} = {P}^{PDG} - {P}^{T P T} \\ Δ {P}^{p i p e} = {P}^{T P T} - {P}^{o u t} \\ Δ {T}^{well} = {T}^{PDG} - {T}^{T P T} \\ Δ {T}^{p i p e} = {T}^{T P T} - {T}^{o u t}\end{matrix}$$

where the pressure values measured in the well and in the pipe comprise:
pressure value measured in the permanent background sensor, (PDG) (P^{PDG});
pressure value measured in the pressure and temperature transducer (TPT) (P^{TPT}); and
pressure value measured at outlet (Pout);

where the temperature values measured in the well and in the pipe comprise:
temperature value measured in PDG (T^{PDG});
temperature value measured in TPT (T^{TPT});
temperature value measured at the outlet (Tout);
calculate auxiliary variables (A, B); where the auxiliary variables are vectors, obtained through:

$$\begin{matrix}A = {( Δ {P}^{T} Δ P )}^{- 1} Δ {P}^{T} ∈ {ℝ}^{2} \\ B = {( Δ {T}^{T} Δ T )}^{- 1} Δ {T}^{T} ∈ {ℝ}^{2}\end{matrix}$$

set at least one method iteration termination criterion of the method;
set initial values for the adjustment factors (3), where the adjustment factors are: well pressure adjustment factor (φP^{well}); well temperature adjustment factor (φT^{well}); pipe pressure adjustment factor (φP^{pipe}); and pipe temperature adjustment factor (φT^{pipe});
perform a first multiphase flowability simulation for a plurality of production tests with the initial values set for the adjustment factors;
update the well pressure adjustment factor (φP^{well}); the well temperature adjustment factor (φT^{well}); the pipe pressure adjustment factor (φP^{pipe}); and the pipe temperature adjustment factor (φT^{pipe}), based on:

$$\begin{matrix}{φ}_{P}^{w e l l} = \frac{{φ}_{P}^{w e l l}}{{( Δ {P}^{w e l {l}^{T}} Δ {P}^{w e l l} )}^{- 1} Δ {P}^{w e l {l}^{T}} {w e l l}^{}} \\ {φ}_{T}^{w e l l} = \frac{{φ}_{T}^{w e l l}}{{( Δ {T}^{w e l {l}^{T}} Δ {T}^{w e l l} )}^{- 1} Δ {T}^{w e l {l}^{T}} {w e l l}^{}} \\ {φ}_{P}^{p i p e} = \frac{{φ}_{P}^{p i p e}}{{A}_{2}} \\ {φ}_{T}^{p i p e} = \frac{{φ}_{T}^{p i p e}}{{B}_{2}}\end{matrix}$$

where:

A₂ is the second element of vector A;

B₂ is the second element of vector B;

$$\begin{matrix}= {\hat{P}}^{P D G} - {\hat{P}}^{T P T} \\ {pipe}^{} = {\hat{P}}^{T P T} - {\hat{P}}^{out} \\ = {\hat{T}}^{P D G} - {\hat{T}}^{T P T} \\ {pipe}^{} = {\hat{T}}^{T P T} - {\hat{T}}^{o u t}\end{matrix}$$

$$AND , {pipe}^{} , , {pipe}^{} ∈ {ℝ}^{{N}_{t e s t s}}$$

determine upper and lower limits on adjustment factors;
perform a second multiphase flowability simulation for a plurality of production tests with the adjustment values set from the previous step of determining upper and lower limits on the adjustment factors;
verify if the convergence criterion has been met; and
achieve optimized adjustment factors.

In addition, the pressure values measured in the PDG, TPT, and outlet are, respectively, stored in the vectors p^{PDG}, p^{TPT}, p^{out}∈ [symbol] ^{Ntests}, where the first element of each vector corresponds to the value measured in a first production test, the second element of each vector corresponds to the value measured in a second production test, and so on.

Similarly, the temperature values measured in the PDG, TPT, and outlet are, respectively, stored in the vectors T^{PDG}, T^{TPT}, T^{out}∈ [symbol] ^{Ntests}, where the first element of each vector corresponds to the value measured in a first production test, the second element of each vector corresponds to the value measured in a second production test, and so on.

The pressure variation in the well (ΔP^{well}) and the pressure variation in the pipe (ΔP^{pipe}) are vectors and ΔP^{well} ΔP^{pipe}∈ [symbol] ^{Ntests}. The temperature variation in the well (ΔT^{well}) and the temperature variation in the pipe (ΔT^{pipe}) are vectors and ΔT^{well}, ΔT^{pipe}∈ [symbol] ^{Ntests}.

In addition, the method for optimizing adjustment factors of multiphase flowability models additionally comprises obtaining a pressure variation matrix (ΔP) and a temperature variation matrix (ΔP), respectively, based on:

$$\begin{matrix}Δ P = [ Δ {P}^{w e l l} , Δ {P}^{p i p e} ] ∈ {ℝ}_{test {s}^{{x}^{2}}}^{N} \\ Δ T = [ Δ {T}^{w e l l} , Δ {T}^{p i p e} ] ∈ {ℝ}_{test {s}^{{x}^{2}}}^{N}\end{matrix}$$

Specifically, the step of defining at least one method iteration termination criterion comprises setting a maximum threshold value for the variation of the objective function, where a suggested maximum threshold value for the variation of the objective function is less than 10⁻³.

More specifically, the step of defining at least one method iteration termination criterion comprises defining a maximum number of iterations where a suggested maximum number of iterations is equal to 20.

Additionally, the step of defining initial values for the pressure and temperature adjustment factors comprises setting the well pressure adjustment factor (φP^{well}) to 1; well temperature adjustment factor (φT^{well}) to 1; pipe pressure adjustment factor (φP^{pipe}) to 1; and pipe temperature adjustment factor (φT^{pipe}) to 1.

The step of performing a first multiphase flowability simulation comprises calculating and storing the values of:
pressure prediction variable calculated in PDG (\hat{P}ᵢ_{^{PDG}});
pressure prediction variable calculated in TPT [symbol] ᵢ_{^{TPT}});
pressure prediction variable calculated at the outlet (\hat{P}ᵢ_{^{out}});
temperature prediction variable calculated in PDG (\hat{T}ᵢ_{^{PDG}});
temperature prediction variable calculated in TPT (\hat{T}ᵢ_{^{TPT}});
temperature prediction variable calculated at the outlet (\hat{T}ᵢ_{^{out}}).

In this sense, the pressure prediction variable calculated in PDG (\hat{P}ᵢ_{^{PDG}}); the pressure prediction variable calculated in TPT (\hat{P}ᵢ_{^{TPT}}); the pressure prediction variable calculated at the outlet (\hat{P}ᵢ_{^{out}}); the temperature prediction variable calculated in PDG (\hat{T}ᵢ_{^{PDG}}); the temperature prediction variable calculated in TPT (\hat{T}ᵢ_{^{TPT}}); and the temperature prediction variable calculated at the outlet (\hat{T}ᵢ_{^{out}}) are stored in vector format, where \hat{P}^{PDG}, \hat{P}^{TPT}, \hat{P}^{out}, \hat{T}^{PDG}, \hat{T}^{TPT}, \hat{T}^{out}∈ [symbol] ^{N}^{ₜₑₛₜₛ}.

Particularly, the step of determining upper and lower limits on the adjustment factors (6) involves defining:
the upper limit of the well pressure adjustment factor (φP^{well}) according to φP^{well}=max(φP^{well}, 0.8);
the lower limit of the well pressure adjustment factor (φP^{well}) according to φP^{well}=min(φP^{well}, 1.2);
the upper limit of the well temperature adjustment factor (φT^{well}), according to φT^{well}=max(φT^{well}, 0.8);
the lower limit of the well temperature adjustment factor (φT^{well}), according to φT^{well}=min(φT^{well}, 1.2);
the upper limit of the pipe pressure adjustment factor φP^{pipe} is set according to equation 19: φP^{pipe}=max(φP^{pipe}, 0.8);
the lower limit of the pipe pressure adjustment factor (φP^{pipe}) according to φP^{pipe}=min(φP^{pipe}, 1.2);
the upper limit of the pipe temperature adjustment factor (φT^{pipe}) according to φT^{pipe}=max(φT^{pipe}, 0.8);
the lower limit of the pipe temperature adjustment factor (φT^{pipe}) according to φT^{pipe}=min(φT^{pipe}, 1.2);

The step of performing a second multiphase flowability simulation comprises calculating and storing the values of:
pressure prediction variable calculated in PDG (\hat{P}ᵢ_{^{PDG}});
pressure prediction variable calculated in TPT (\hat{P}ᵢ_{^{TPT}});
pressure prediction variable calculated at the outlet (\hat{P}ᵢ_{^{out}});
temperature prediction variable calculated in PDG (\hat{T}ᵢ_{^{PDG}});
temperature prediction variable calculated in TPT (\hat{T}ᵢ_{^{TPT}});
temperature prediction variable calculated at the outlet (\hat{T}ᵢ_{^{out}}).

It should be noted that the upper and lower limits on the adjustment factors can be determined at the user's discretion.

In this sense, the pressure prediction variable calculated in PDG (\hat{P}ᵢ_{^{PDG}}); the pressure prediction variable calculated in TPT (\hat{P}ᵢ_{^{TPT}}); the pressure prediction variable calculated at the outlet (\hat{P}ᵢ_{^{out}}); the temperature prediction variable calculated in PDG (\hat{T}ᵢ_{^{PDG}}); the temperature prediction variable calculated in TPT (\hat{T}ᵢ_{^{TPT}}); and the temperature prediction variable calculated at the outlet (\hat{T}ᵢ_{^{out}}) are stored in vector format, where \hat{P}^{PDG}, \hat{P}^{TPT}, \hat{P}^{out}, \hat{T}^{PDG}, \hat{T}^{TPT}, \hat{T}^{out}∈ [symbol] ^{N}^{ₜₑₛₜₛ}.

The step of verifying whether the convergence criterion was met includes verifying whether the method iteration termination criterion, defined in the second step, was met; where if the method iteration termination criterion was not met, it is returned to the step of updating the well pressure adjustment factor (φP^{well}); the well temperature adjustment factor (φT^{well}); the pipe pressure adjustment factor (φP^{pipe}); and the pipe temperature adjustment factor (φT^{pipe}); or if the method iteration termination criterion was met, perform the step of obtaining optimized adjustment factors.

In addition, according to another preferential embodiment of the present invention, a computer-readable storage medium is defined, comprising, stored in itself, a set of computer-readable instructions, which when executed by a computer, carry out the method to optimize adjustment factors of multiphase flowability models.

### BRIEF DESCRIPTION OF THE FIGURES

To enhance this description and provide a clearer insight into the features of the present invention, and in accordance with a preferred embodiment thereof, a set of accompanying figures is included. These figures exemplify, though not exhaustively, the preferred embodiment.

FIG. 1 shows the flowchart of the method for optimizing adjustment factors of multiphase flowability models.

FIG. 2 illustrates a schematic representation of the offshore well, according to a comparative case study.

FIG. 3 shows the history of the optimization of the adjustment factors following the execution of the method of the present invention, according to an exemplifying application of the method of the present invention.

FIG. 4 shows the history of the optimization of the adjustment factors following the execution of the algorithm (i) of document BR 102021026238-9.

FIG. 5 shows the history of the optimization of the adjustment factors following the execution of the ADAM algorithm.

FIG. 6 shows the history of the optimization of the adjustment factors following the execution of the Davidon-Fletcher-Powell (DFP) algorithm.

FIG. 7 shows the history of the optimization of the adjustment factors following the execution of the CMA-ES algorithm.

FIG. 8 elucidates the history of the optimization of the adjustment factors following the execution of the Hooke-Jeeves (HJ) algorithm.

FIG. 9 shows the EPAM value obtained by each algorithm at each iteration.

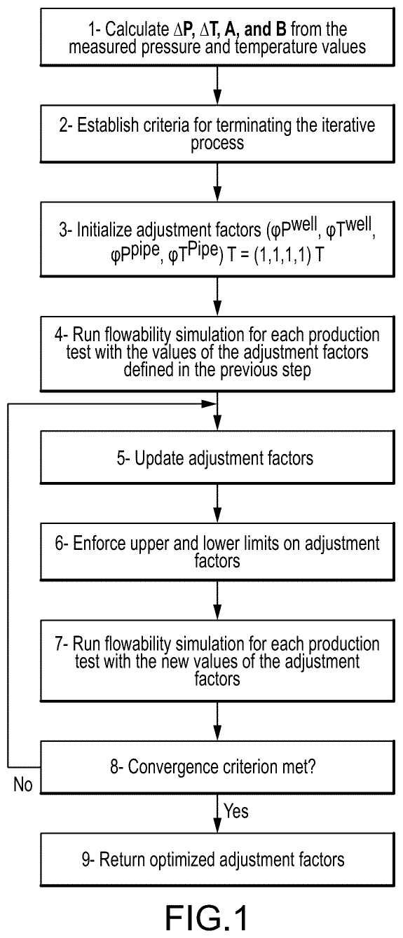

### DETAILED DESCRIPTION OF THE INVENTION

The method for optimizing adjustment factors of multiphase flowability models, according to a preferred

Embodiment of the present invention, is described in detail below, based on the attached figures.

First, it should be noted that finding the adjustment factors that reduce the error of a specific multiphase flow model is an optimization problem.

The adjustment factors to be optimized are the variables.

Constraints are the upper and lower limits at which adjustment factors are allowed to vary.

The objective function to be minimized evaluates the prediction errors of the flowability model in relation to the measured data.

In O&G applications, field data is usually obtained during production testing, as producing wells are required to undergo periodic testing for regulatory compliance purposes. In these tests, production is diverted to a test separator, which is used to separate and measure the flow rates of oil, gas, and water.

The method for optimizing adjustment factors of multiphase flowability models comprises the steps of:
Step 1—Calculate pressure variation and temperature variation;
Step 2—Set method iteration termination criterion;
Step 3—Set initial values for the pressure and temperature adjustment factors;
Step 4—Perform a first multiphase flowability simulation;
Step 5—Update adjustment factors;
Step 6—Determine upper and lower limits on adjustment factors;
Step 7—Perform a second multiphase flowability simulation;
Step 8—Verify if the convergence criterion has been met; and
Step 9—achieve optimized adjustment factors.

Specifically, each step of the method of this invention will be described in more detail below.

### Step 1—Calculate Pressure Variation and Temperature Variation

Step 1 comprises calculating the variation in pressure ΔP in the well ΔP^{well} and the pipe ΔP^{well} and the variation in temperature ΔT in the well and pipe, based on pressure and temperature values measured in the well and pipe.

In addition, step 1 includes calculating auxiliary variables A and B for the calculation of adjustment factors; where A and B are vectors.

Specifically, the pressure values measured in the well and pipe comprise:
pressure value measured in the permanent background sensor, (PDG, Permanent Downhole Gauge) P^{PDG};
pressure value measured in the pressure and temperature transducer (TPT) (P^{TPT}); and
pressure value measured at outlet P^{out}.

Specifically, the temperature values measured in the well and pipe comprise:
temperature value measured in the permanent background sensor, (PDG, Permanent Downhole Gauge) T^{PDG};
temperature value measured in the pressure and temperature transducer (TPT) T^{TPT};
temperature value measured at the outlet T^{out}.

In these terms, it is considered that the pressure values measured in the PDG, TPT, and outlet are, respectively, stored in the vectors p^{PDG}, p^{TPT}, p^{out}∈ [symbol] ^{Ntests}, where the first element of each vector corresponds to the value measured in a first production test, the second element of each vector corresponds to the value measured in a second production test, and so on.

Similarly, it is considered that the temperature values measured in the PDG, TPT, and outlet are, respectively, stored in the vectors T^{PDG}, T^{TPT}, T^{out}∈ [symbol] ^{Ntests}, where the first element of each vector corresponds to the value measured in a first production test, the second element of each vector corresponds to the value measured in a second production test, and so on.

More specifically, step 1 comprises calculating the variation in pressure in the well ΔP^{well} and the variation in pressure in the pipe ΔP^{pipe} from the measured pressure values P^{PDG}, P^{TPT} and P^{out}, according to equations 1 and 2, respectively:

$$Δ {P}^{well} = {P}^{PDG} - {P}^{T P T} \qquad equation 1$$

$$Δ {P}^{p i p e} = {P}^{T P T} - {P}^{out} \qquad Equation 2$$

wherein ΔP^{well}, ΔP^{pipe} are vectors; and ΔP^{well}, ΔP^{pipe}∈ [symbol] ^{Ntests}.

In addition, step 1 consists of calculating the variation in temperature in the well ΔT^{well} and the variation in temperature in the ΔT^{pipe}, from the measured temperature values T^{PDG}, T^{TPT} and T^{out}, according to equations 3 and 4, respectively:

$$Δ T w e l l = {T}^{PDG} - {T}^{T P T} \qquad Equation 3$$

$$Δ Tpipe = {T}^{T P T} - {T}^{out} \qquad Equation 4$$

wherein ΔT^{well}, ΔT^{pipe} are vectors; and ΔT^{well}, ΔT^{pipe}∈ [symbol] ^{Ntests}.

From the vectors ΔP^{well}, ΔP^{pipe}, ΔT^{well}, ΔT^{pipe}, the matrices of variation in pressure ΔP and variation in temperature ΔT are obtained, respectively, as follows:

$$\begin{matrix}Δ P = [ Δ {P}^{w e l l} , Δ {P}^{p i p e} ] ∈ {ℝ}_{test {s}^{{x}^{2}}}^{N} \\ Δ T = [ Δ {T}^{w e l l} , Δ {T}^{p i p e} ] ∈ {ℝ}_{test {s}^{{x}^{2}}}^{N}\end{matrix}$$

From the matrices ΔP and ΔT, the auxiliary variables A and B are calculated, through equations 5 and 6, respectively:

$$A = {( Δ {P}^{T} Δ P )}^{- 1} Δ {P}^{T} {p i p e}^{} ∈ {ℝ}^{2} \qquad equation 5$$

$$B = {( Δ {T}^{T} Δ T )}^{- 1} Δ {T}^{T} {p i p e}^{} ∈ {ℝ}^{2} \qquad equation 6$$

### Step 2—Set at Least One Criterion for Terminating the Iterative Process

The user can set the conditions for the iterative process to stop. For example, the user can set any of the iterative process termination criteria among: absolute value of the difference between the calculated errors in two consecutive iterations is less than a maximum threshold value for the variation of the objective functions; or a maximum number of iterations Nₘₐₓ; or any other iterative process termination criteria.

Regarding the calculated error metric in two consecutive iterations, an example would be the mean percentage absolute error between the measured and calculated values of pressure and temperature. However, any other error metric can be used, and the criteria for stopping the iterative process can also be changed.

It is worth noting that the lower the maximum threshold value for the variation of the objective function ε, the stricter the criterion for optimization convergence and, therefore, a longer convergence delay is expected.

Regarding the maximum number of iterations Nₘₐₓ, this indicates the maximum number of iterations until the method is interrupted, and prevents the method from performing iterations indefinitely (the so-called “infinite loop”).

In addition, it is important to note that a simulation that terminates because it has reached the maximum number of iterations Nₘₐₓ did not necessarily converge to the optimal solution. Therefore, it is important for the user experience to set a maximum number of iterations Nₘₐₓ specific to the problem at hand that allows convergence to the optimal solution.

As from a preferred embodiment of the method of the present invention, step 2 comprises defining at least one iterative process termination criteria as a maximum threshold value for the variation of the objective function ε, for example, where ε<10⁻³.

According to another preferred embodiment of the method of this invention, step 2 comprises defining at least one iterative process termination criteria as a maximum number of iterations Nₘₐₓ, for example, where Nₘₐₓ=20.

### Step 3—Set Initial Values for the Adjustment Factors

According to a preferred embodiment of the present invention, step 3 comprises defining initial values for the adjustment factors, where the adjustment factors are:
well pressure adjustment factor φP^{well}, where φP^{well}=1;
well temperature adjustment factor φT^{well}, where φT^{well}=1;
pipe pressure adjustment factor φP^{pipe}, where φT^{pipe}=1; and
pipe temperature adjustment factor φT^{pipe}, where φT^{pipe}=1;
where (φP^{well}, φT^{well}, φP^{pipe}, φT^{pipe})^{T}=(1, 1, 1, 1)^{T}.

### Step 4—Perform a First Multiphase Flowability Simulation

Step 4 comprises performing a first multiphase flowability simulation for each production test with the initial values for the adjustment factors set in step 3, i.e., where (φP^{well}, φT^{well}, φP^{pipe}, φT^{pipe})^{T}=(1, 1, 1, 1)^{T}.

With the initial values of the adjustment factors set in step 3, multiphase flowability simulations are performed for a plurality of production testing i (i=1, . . . , Nₜₑₛₜₛ), in which each test has its specific boundary conditions.

Each simulation of the production test produces a pressure and temperature profile. Thus, step 4 additionally includes calculating and storing, for each production test i (i=1, . . . , Ntests), the values of:
\hat{P}ᵢ^{PDG}: pressure prediction variable calculated in PDG;
\hat{P}ᵢ^{TPT}: pressure prediction variable calculated in TPT;
\hat{P}ᵢ^{out}: pressure prediction variable calculated at the outlet;
\hat{T}ᵢ^{PDG}: temperature prediction variable calculated in PDG;
\hat{T}ᵢ^{TPT}: temperature prediction variable calculated in TPT; and
\hat{T}ᵢ^{out}: temperature prediction variable calculated at the outlet.

Specifically, the variables \hat{P}^{PDG}, \hat{P}^{TPT}, \hat{P}^{out}, \hat{T}^{PDG}, \hat{T}^{TPT}, \hat{T}^{out} are stored in vector format, where \hat{P}^{PDG}, \hat{P}^{TPT}, \hat{P}^{out}, \hat{T}^{PDG}, \hat{T}^{TPT}, \hat{T}^{out}∈ [symbol] ^{N}^{ₜₑₛₜₛ}.

### Step 5-Update Adjustment Factors

Step 5 of updating adjustment factors involves updating the pressure adjustment factors of φP^{well}, well temperature φT^{well}, pipe pressure φP^{pipe}, and pipe temperature φT^{pipe}, respectively, according to equations 7, 8, 9, and 10:

$${φ}_{P}^{w e l l} = \frac{{φ}_{P}^{w e l l}}{{( Δ {P}^{w e l {l}^{T}} Δ {P}^{w e l l} )}^{- 1} Δ {P}^{w e l {l}^{T}} {w e l l}^{}} \qquad equation 7$$

$${φ}_{T}^{w e l l} = \frac{{φ}_{T}^{w e l l}}{{( Δ {T}^{{well}^{T}} Δ {T}^{w e l l} )}^{- 1} Δ {T}^{{well}^{T}} {w e l l}^{}} \qquad equation 8$$

$${φ}_{P}^{p i p e} = \frac{{φ}_{P}^{p i p e}}{{A}_{2}} \qquad equation 9$$

$${φ}_{T}^{p i p e} = \frac{{φ}_{T}^{p i p e}}{{B}_{2}} \qquad equation 10$$

where:
A₂ is the second element of vector A;
B₂ is the second element of vector B;
[symbol] ^{well} is the pressure prediction in the well, calculated in equation 11 below;
[symbol] ^{pipe} is the pressure prediction in the pipe, calculated in equation 12 below;
[symbol] ^{well} is the temperature prediction in the well, calculated in equation 13 below;
[symbol] ^{pipe} is the temperature prediction in the pipe, calculated in equation 14 below; and

$${w e l l}^{} = {\hat{P}}^{P D G} - {\hat{P}}^{T P T} \qquad equation 11$$

$${p i p e}^{} = {\hat{P}}^{T P T} - {\hat{P}}^{out} \qquad equation 12$$

$${w e l l}^{} = {\hat{T}}^{P D G} - {\hat{T}}^{T P T} \qquad equation 13$$

$${p i p e}^{} = {\hat{T}}^{T P T} - {\hat{T}}^{out} \qquad equation 14$$

$$Where {w e l l}^{} , {p i p e}^{} , {w e l l}^{} , {p i p e}^{} ∈ {ℝ}^{{N}_{t e s t s}} ; \qquad equation 15$$

### Step 6-Determine Upper and Lower Limits on Adjustment Factors

Step 6 comprises determining upper and lower limits on adjustment factors, where:
the upper limit of the well pressure adjustment factor φP^{well}. For example, for a maximum change of 20%, φP^{well} is set according to equation 15: φP^{well}=max(φP^{well}, 0.8);
the lower limit of the well pressure adjustment factor φP^{well}. For example, for a maximum change of 20%, φP^{well} is set according to equation 16: φP^{well}=min(φP^{well}, 1.2);
the upper limit of the well temperature adjustment factor φT^{well}. For example, for a maximum change of 20%, φT^{well} is set according to equation 17: φT^{well}=max(φT^{well}, 0.8);
the lower limit of the well temperature adjustment factor φT^{well}. For example, for a maximum change of 20%, φT^{well} is set according to equation 18: φT^{well}=min(φT^{well}, 1.2);
the upper limit of the pipe pressure adjustment factor Ppipe φP^{pipe}. For example, for a maximum change of 20%, φP^{pipe} is set according to equation 19: φP^{pipe}=max(φP^{pipe}, 0.8);
the lower limit of the pipe pressure adjustment factor φP^{pipe}. For example, for a maximum change of 20%, φP^{pipe} is set according to equation 20: φP^{pipe}=min(φP^{pipe}, 1.2);
the upper limit of the pipe temperature adjustment factor φT^{pipe}. For example, for a maximum change of 20%, φT^{pipe} is set according to equation 21: φT^{pipe}=max(φT^{pipe}, 0.8);
the lower limit of the pipe temperature adjustment factor φT^{pipe}. For example, for a maximum change of 20%, φT^{pipe} is set according to equation 22: φT^{pipe}=min(T^{pipe}, 1.2);

### Step 7—Perform a Second Multiphase Flowability Simulation

Step 7 consists of performing a second multiphase flowability simulation for a plurality of production tests i (i=1, . . . , Nₜₑₛₜₛ) with the new values of the adjustment factors, as set in the previous step, step 6.

Step 7 is analogous to step 4 of the present invention method, described above.

More specifically, step 7 involves updating the values of the adjustment factors to the values of the respective variables φP^{well}, φT^{well}, φP^{pipe}, φT^{pipe}, in the flowability model of the well for which the measured pressure and temperature values are obtained.

Each second simulation of the production test produces a pressure and temperature profile. Thus, step 7 additionally includes calculating and storing, for each production test i (3=1, . . . , Nₜₑₛₜₛ):
\hat{P}ᵢ^{PDG}: pressure prediction variable calculated in PDG;
\hat{P}ᵢ^{TPT}: pressure prediction variable calculated in TPT;
\hat{P}ᵢ^{out}: pressure prediction variable calculated at the outlet;
\hat{T}ᵢ^{PDG}: temperature prediction variable calculated in PDG;
\hat{T}ᵢ^{TPT}: temperature prediction variable calculated in TPT; and
\hat{T}ᵢ^{out}: temperature prediction variable calculated at the outlet.

Specifically, the variables \hat{P}^{PDG}, \hat{P}^{TPT}, \hat{P}^{out}, \hat{T}^{PDG}, \hat{T}^{TPT}, \hat{T}^{out} are stored in vector format, where \hat{P}^{PDG}, \hat{P}^{TPT}, \hat{P}^{out}, \hat{T}^{PDG}, \hat{T}^{TPT}, \hat{T}^{out}∈ [symbol] ^{N}^{ₜₑₛₜₛ}.

Step 8—Verify if the Convergence Criterion has been Met

Step 8 comprises verifying whether the convergence criterion has been met, including verifying whether the method iteration termination criterion, set in step 2, has been met.

If the method iteration termination criterion set in step 2 is not met, the process returns to step 5.

If the method iteration termination criterion set in step 2 is met, the method proceeds to the next step, step 9, to obtain optimized adjustment factors.

At each iteration, the method of the present invention calculates the new values for the adjustment factors (in the pressure and temperature gradients) based only on the results of the flow simulation performed with the values of the adjustment factors obtained in the previous iteration.

### Step 9—Achieve Optimized Adjustment Factors

Step 9 involves obtaining optimized adjustment factors for well pressure φP^{well}, well temperature φT^{well}, pipe pressure φP^{pipe}, and pipe temperature φT^{pipe}, where the optimized adjustment factors are those from the last method iteration.

In accordance with a further preferential embodiment of the present invention, the method for optimizing adjustment factors of multiphase flowability models may be implemented by means of a computer-readable instruction set or processor or machine, where the instruction set is executed by one or more computers or processors or machines, where the instruction set may be stored or written to a computer-readable storage medium, or processor or machine. The processing of the instruction set that play the method for optimizing adjustment factors of multiphase flowability models of this invention. On the other hand, the set of computer-readable instructions represents a computer program, computer program code, or application.

In particular, computer-readable storage medium can be memory, where the memory can be non-volatile, such as a hard disk drive (HDD) or solid-state drive (SSD), or it can be volatile memory, such as a random-access memory (SSD), or it can be volatile memory, such as a random-access memory, RAM). In addition, the readable storage media can be any other medium that can transport, store, or write the expected program code in the form of an instruction or a data structure, or a set of instructions, and it can be accessed by a computer, processor, or machine, but is not limited to them. The readable storage media can alternatively be a circuit or any other apparatus that can implement a storage function.

Specifically, the set of computer-readable instructions represents the algorithm or computer program code, or a data structure, which performs the method for optimizing adjustment factors of multiphase flowability models described above.

The computer, processor, or machine can be a general-purpose processor, which may be a microprocessor or any conventional or similar processor.

### Invention Results

In order to demonstrate the performance of the proposed method and its competitive advantage over the methods available in the state of the art, a comparative case study is presented below.

Calibrating a real well model is used as an example. The adjustment factors are calculated based on:
method to optimize adjustment factors of multiphase flowability models of the present invention;
(i) method proposed in document BR 102021026238-9; and
four other alternative optimization methods that employ different space exploration strategies include:
(ii) ADAM algorithm by Kingma, D. P., Ba, J., 2014.
Adam: A method for stochastic optimization. arXiv preprint arXiv: 1412.6980;
(iii) Davidon-Fletcher-Powell (DFP) algorithm by Davidon, W. C., 1959. Variable metric method for minimization. Technical Report. Argonne National Laboratory. doi: 10.2172/4252678; and Fletcher, R., Powell, M. J., 1963. A rapidly convergent descent method for minimization. The Computer Journal 6, 163-168;
(iv) CMA-ES algorithm by Hansen, N., 2006. The CMA evolution strategy: a comparing review. Towards a New Evolutionary Computation, 75-102;
and
(v) Hooke-Jeeves (HJ) algorithm by Hooke, R., Jeeves, T. A., 1961. “Direct Search” Solution of Numerical and Statistical Problems. Journal of the ACM (JACM) 8, 212-229.

In particular, the optimization aims to minimize the mean absolute percentage error (MAPE) between the measured and calculated values of pressure PPDG and temperature TPDG measured by the permanent downhole gauge (PDG); measured and calculated values of pressure PTPT and temperature TTPT measured by the pressure and temperature transducer (TPT); and the outlet temperature Tout during production tests.

In this comparative case study, the “outlet” position denotes the production choke, where sensors are for measuring pressure and temperature. Such measured values are reported in Table 1 below.

TABLE 1
Operational data measured
during nine production tests

| Production | PPDG | TPDG | PTPT | TTPT | Tout |
|---|---|---|---|---|---|
| test | (barg) | (° C.) | (barg) | (° C.) | (° C.) |
| 1 | 215.0 | 60.3 | 132.3 | 54.4 | 35.3 |
| 2 | 212.4 | 60.4 | 126.9 | 53.2 | 38.8 |
| 3 | 212.3 | 60.6 | 125.4 | 53.3 | 39.3 |
| 4 | 213.6 | 60.6 | 125.7 | 53.7 | 41.4 |
| 5 | 215.6 | 60.8 | 127.4 | 54.3 | 42.2 |
| 6 | 216.8 | 60.8 | 126.3 | 54.8 | 43.9 |
| 7 | 216.8 | 60.9 | 126.2 | 54.9 | 43.3 |
| 8 | 217.7 | 60.9 | 126.7 | 55.0 | 44.0 |
| 9 | 218.1 | 61.0 | 127.4 | 55.0 | 44.0 |

The adjustment factors vary within an allowable range between an upper limit of 1.2 and a lower limit of 0.8. In addition, a maximum number Nₘₐₓ iterations of 20 is allowed.

### Description of the Comparative Case Study

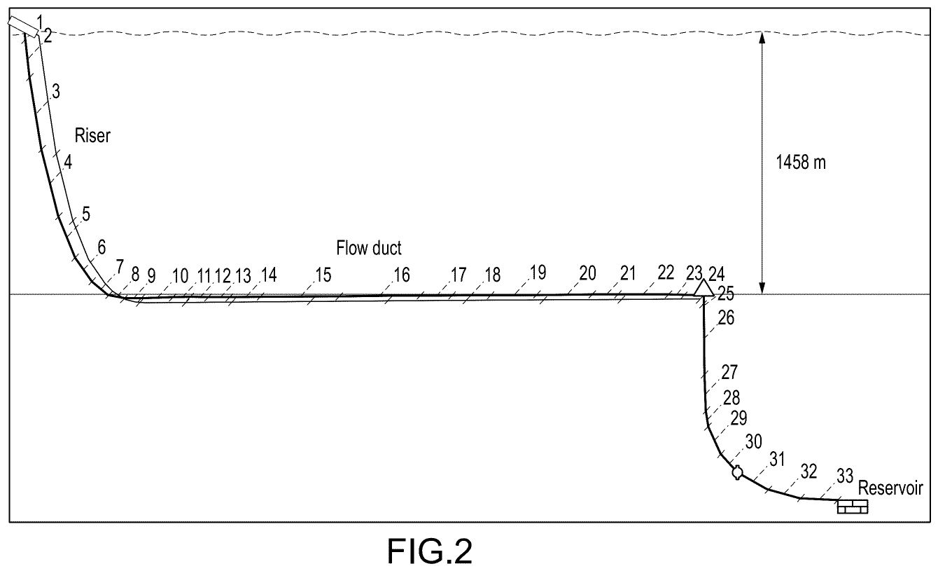

The offshore well is located in the Campos Basin and utilizes gas-lift for production. A schematic representation of the well, along with its main features, can be found in FIG. 2. According to FIG. 2, the length of the riser plus the length of the flow duct is 4953 meters; the well length is 1656 meters.

Flowability simulations are performed with a private simulator, which provides pressure and temperature profiles.

The analysis incorporates nine production tests carried out over a period of 2.5 years, so that the calibrated model is representative of the production history.

The boundary conditions required for these flow simulations include the outlet pressure (Pout), reservoir temperature, produced liquid flow rate (Qliq), watercut (WC), gas-to-oil ratio (RGO), as well as the gas-lift flow rate (Qg1) and gas-lift injection temperature.

Table 2 below presents the boundary conditions associated with each production test.

TABLE 2
Boundary conditions for
the nine production tests

| Production | Pout | Qliq | WC | Qg1 |
|---|---|---|---|---|
| test | (barg) | (Sm³/d) | (%) | (Sm³/d) |
| 1 | 27. | 4146 | 0.6 | 268522 |
| 2 | 20.0 | 4144 | 12.7 | 216059 |
| 3 | 13.9 | 4347 | 19.2 | 256944 |
| 4 | 139 | 4357 | 31.9 | 261032 |
| 5 | 12.5 | 4303 | 38.1 | 254150 |
| 6 | 12.7 | 4182 | 40.4 | 260798 |
| 7 | 12.6 | 4155 | 46.4 | 258019 |
| 8 | 11.8 | 4193 | 44.0 | 257558 |
| 9 | 12.0 | 4157 | 45.5 | 263600 |

Throughout these nine tests, reservoir and gas-lift injection temperatures remain constant at 61° C. and 40° C., respectively, with the RGO maintained at 69 Sm³/Sm³.

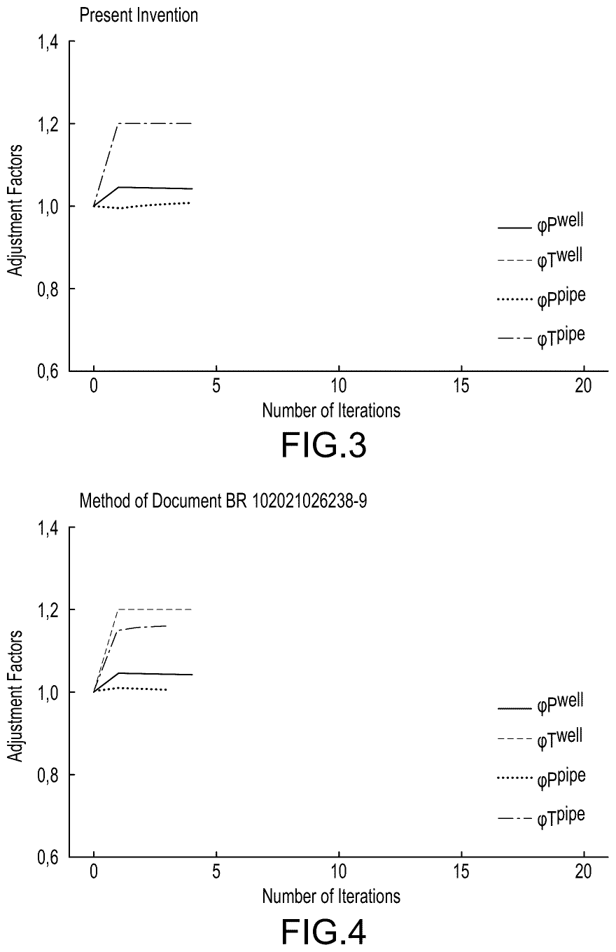

FIGS. 3-8 show the history of the optimization of the adjustment factors for the algorithms used in the comparative case study.

FIG. 3 shows the history of the optimization of the adjustment factors following the execution of the method of the present invention, according to an exemplifying application of the method of the present invention, in the present comparative case study.

FIG. 4 shows the history of the optimization of the adjustment factors following the execution of the algorithm (i) of document BR 102021026238-9.

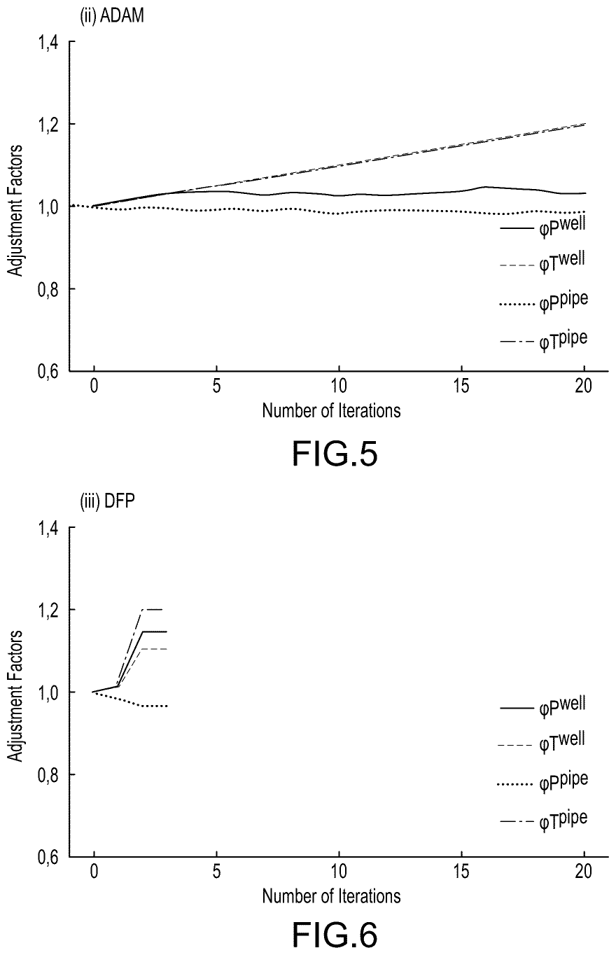

FIG. 5 illustrates the history of the optimization of the adjustment factors following the execution of the ADAM (ii) algorithm.

FIG. 6 shows the history of the optimization of the adjustment factors following the execution of the DFP (iii) algorithm.

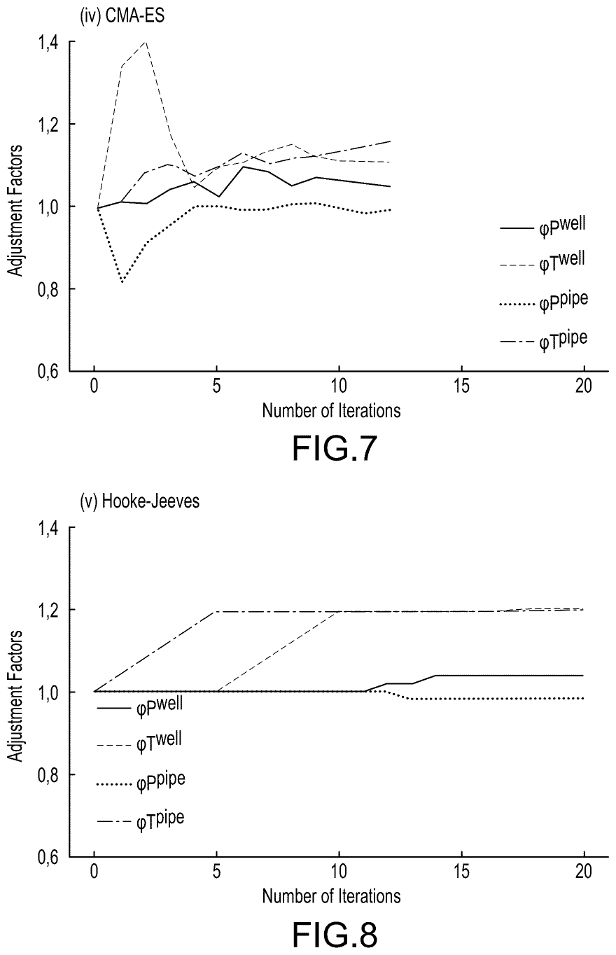

FIG. 7 shows the history of the optimization of the adjustment factors following the execution of the CMA-ES (iv) algorithm.

FIG. 8 elucidates the history of the optimization of the adjustment factors following the execution of the HJ (v) algorithm.

Compared to the one proposed by document BR 102021026238-9, the present invention provides a calibrated model with lower EPAM, as shown in FIG. 3.

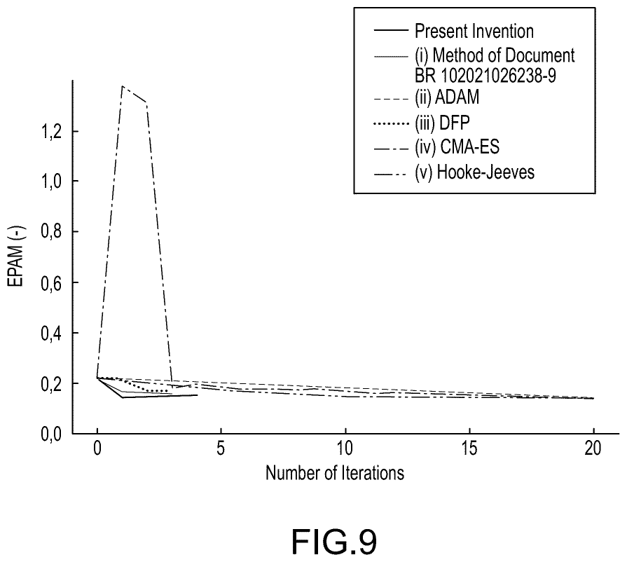

FIG. 9 shows the mean absolute percentage error (MAPE) value obtained by each algorithm in the comparative case study at each iteration.

The Hooke-Jeeves (HJ) (v) algorithm achieves the lowest MAPE among all the algorithms tested.

Table 3 below shows the normalized computational cost of each algorithm.

TABLE 3
Comparison of computational time for adjustment factor optimization

| | Present | (i)BR | (ii) | (iii) | (iv) | |
|---|---|---|---|---|---|---|
| | invention | 102021026238-9 | ADAM | DFP | CMA-ES | (v) HJ |
| Normalized | 1 | 0.82 | 35.94 | 35.37 | 30.98 | 32.20 |
| computational | | | | | | |
| time | | | | | | |

From table 3, it can be seen that heuristic methods, such as the one of the present invention and the one proposed by (i) BR 102021026238-9, are extremely faster than generic algorithms, such as (ii) ADAM, (iii) DFP, (iv) CMA-ES and (v) HJ.

When compared to the Hooke-Jeeves method, which achieves the lowest MAPE among all the algorithms tested, the method of the present invention achieves an 8% higher MAPE over a period of time 32 times faster.

The method of the present invention produces highly competitive results with a significantly reduced computational cost. For example, the adjustment factors obtained with the present invention can be used as an informed initial guess in generic optimization algorithms, should more fine-grained optimization be required.

In addition, the method of the present invention produces excellent results for the optimization of adjustment factors applied to pressure and temperature gradients with a low computational cost.

In particular, it should be noted that in other comparisons carried out, the method of the present invention is substantially faster than that used in the studies by Monteiro, D. O., Duque, M. C. M. A., Chaves, G. S., Baioco, J. S., Ferreira Filho, V. J., 2018. Model Adjusting and Parameters Estimation under Uncertainties for Multiphase Flow, in: Rio Oil & Gas Expo and Conference; de Chaves, G., Monteiro, D., Martins Ferreira, V. J., 2021. A Back Allocation Methodology to Estimate the Real-Time Flow and Assist Production Monitoring, in: SPE Annual Technical Conference and Exhibition, OnePetro; or Seman, L. O., Miyatake, L. K., Camponogara, E., Giuliani, C. M., Vieira, B. F., 2020. Derivative-free parameter tuning for a well multiphase flow simulator. Journal of Petroleum Science and Engineering 192, 107288.

Thus, the method of the present invention can be used to optimize adjustment factors applied to pressure and temperature gradient in flow simulation models of producing and injecting wells, onshore and offshore.

The skilled in the art will value the knowledge presented herein and can reproduce the invention in the presented embodiments and their variants, which are covered in the scope of the claims below.

1. Method for optimizing adjustment factors of multiphase flowability models, comprising the steps of:
calculate the pressure change (Δp) in a well (ΔP^{well}) and in a pipe (ΔP^{pipe}); and the variation in temperature (ΔT) in a well (ΔT^{well}) and in a pipe (ΔT^{pipe}), based on pressure and temperature values measured in the well and in the pipe, based on:
$$\begin{matrix}Δ {P}^{well} = {P}^{PDG} - {P}^{T P T} \\ Δ {P}^{p i p e} = {P}^{T P T} - {P}^{o u t} \\ Δ {T}^{well} = {T}^{PDG} - {T}^{T P T} \\ Δ {T}^{p i p e} = {T}^{T P T} - {T}^{o u t}\end{matrix}$$
where the pressure values measured in the well and in the pipe comprise:
pressure value measured in the permanent background sensor, (PDG, Permanent Downhole Gauge) (p^{PDG});
pressure value measured on the pressure and temperature transducer (TPT) (P^{TPT}); and
pressure value measured at the outlet (P^{out});
where the temperature values measured in the well and in the pipe comprise:
temperature value measured in PDG (T^{PDG});
temperature value measured in TPT (T^{TPT});
temperature value measured at the outlet (T^{out});
calculate auxiliary variables (A, B); where the auxiliary variables are vectors, obtained through:
$$\begin{matrix}A = {( Δ {P}^{T} Δ P )}^{- 1} Δ {P}^{T} ∈ {ℝ}^{2} \\ B = {( Δ {T}^{T} Δ T )}^{- 1} Δ {T}^{T} ∈ {ℝ}^{2}\end{matrix}$$
set at least one method iteration termination criterion;
set initial values for the adjustment factors, where the adjustment factors are: well pressure adjustment factor (φP^{well}); well temperature adjustment factor (φT^{well}); pipe pressure adjustment factor (φP^{pipe}); and pipe temperature adjustment factor (φT^{pipe});
perform a first multiphase flowability simulation for a plurality of production tests (i) with the initial values set for the adjustment factors;
update the well pressure adjustment factor (φP^{well}); the well temperature adjustment factor (T^{well}); the pipe pressure adjustment factor (φP^{pipe}); and the pipe temperature adjustment factor (φT^{pipe}), based on:
$$\begin{matrix}{φ}_{P}^{w e l l} = \frac{{φ}_{P}^{w e l l}}{{( Δ {P}^{w e l {l}^{T}} Δ {P}^{w e l l} )}^{- 1} Δ {P}^{w e l {l}^{T}} {w e l l}^{}} \\ {φ}_{T}^{w e l l} = \frac{{φ}_{T}^{w e l l}}{{( Δ {T}^{{well}^{T}} Δ {T}^{w e l l} )}^{- 1} Δ {T}^{{well}^{T}} {w e l l}^{}} \\ {φ}_{P}^{p i p e} = \frac{{φ}_{P}^{p i p e}}{{A}_{2}} \\ {φ}_{T}^{p i p e} = \frac{{φ}_{T}^{p i p e}}{{B}_{2}} \\ {w e l l}^{} = {\hat{P}}^{P D G} - {\hat{P}}^{T P T} \\ {p i p e}^{} = {\hat{P}}^{T P T} - {\hat{P}}^{out} \\ {w e l l}^{} = {\hat{T}}^{P D G} - {\hat{T}}^{T P T} \\ {p i p e}^{} = {\hat{T}}^{T P T} - {\hat{T}}^{out}\end{matrix}$$
$$and {w e l l}^{} , {p i p e}^{} , {w e l l}^{} , {p i p e}^{} ∈ {ℝ}^{{N}_{t e s t s}} ;$$
determine upper and lower limits on adjustment factors;
perform a second multiphase flowability simulation for a plurality of production tests (i) with the adjustment values set from the previous step of determining upper and lower limits on the adjustment factors;
verify if the convergence criterion has been met; and
Achieve optimized adjustment factors.

2. Method, according to claim 1, wherein the pressure values measured in the PDG, TPT, and outlet are, respectively, stored in the vectors p^{PDG}, p^{TPT}, p^{out}∈ [symbol] ^{Ntests}, where the first element of each vector corresponds to the value measured in a first production test, the second element of each vector corresponds to the value measured in a second production test, and so on.

3. Method, according to claim 1, wherein the temperature values measured in the PDG, TPT, and outlet are, respectively, stored in the vectors T^{PDG} T^{TPT}, T^{out}∈ [symbol] ^{Ntests}, where the first element of each vector corresponds to the value measured in a first production test, the second element of each vector corresponds to the value measured in a second production test, and so on.

4. Method, according to claim 1, wherein the variation in pressure in the well (ΔP^{well}) and the variation in pressure in the pipe (ΔP^{pipe}) are vectors and ΔP^{well}, ΔP^{pipe}∈ [symbol] ^{Ntests}.

5. Method, according to claim 1, wherein the temperature variation in the well (ΔT^{well}) and the temperature variation in the pipe (ΔT^{pipe}) are vectors and ΔT^{well}, ΔT^{pipe}∈ [symbol] ^{Ntests}.

6. Method, according to claim 1, wherein it additionally comprises obtaining a pressure variation matrix (ΔP) and a temperature variation matrix (ΔP), respectively, based on:
$$\begin{matrix}Δ P = [ Δ {P}^{w e l l} , Δ {P}^{p i p e} ] ∈ {ℝ}_{test {s}^{{x}^{2}}}^{N} \\ Δ T = [ Δ {T}^{w e l l} , Δ {T}^{p i p e} ] ∈ {ℝ}_{test {s}^{{x}^{2}}}^{N}\end{matrix}$$

7. Method, according to claim 1, wherein the step of defining at least one method iteration termination criterion comprises setting a maximum threshold value for the variation of the objective function (ε), where a maximum threshold value for the variation of the objective function is less than 10⁻³.

8. Method, according to claim 1, wherein the step of defining at least one method iteration termination criterion comprises setting a maximum number of iterations (Nₘₐₓ), where the maximum number of iterations is equal to 20.

9. Method, according to claim 1, wherein the step of defining initial values for the pressure and temperature adjustment factors comprises setting the well pressure adjustment factor (φP^{well}) equal to; well temperature adjustment factor (φT^{well}) equal to 1; pipe pressure adjustment factor (φP^{pipe}) equal to 1; and pipe temperature adjustment factor (φT^{pipe}) equal to 1.

10. Method, according to claim 1, wherein the step of performing a first multiphase flowability simulation comprises calculating and storing the values of:
pressure prediction variable calculated in PDG (\hat{P}ᵢ_{^{PDG}});
pressure prediction variable calculated in TPT [symbol] ᵢ_{^{TPT}});
pressure prediction variable calculated at the outlet (\hat{P}ᵢ_{^{out}});
temperature prediction variable calculated in PDG (\hat{T}ᵢ_{^{PDG}});
temperature prediction variable calculated in TPT (\hat{T}ᵢ_{^{TPT}});
temperature prediction variable calculated at the outlet (\hat{T}ᵢ_{^{out}}).

11. Method, according to claim 9, wherein the pressure prediction variable calculated in PDG (\hat{P}ᵢ_{^{PDG}}); the pressure prediction variable calculated in TPT (\hat{P}ᵢ_{^{TPT}}); the pressure prediction variable calculated at the outlet (\hat{P}ᵢ_{^{out}}); the temperature prediction variable calculated in PDG (\hat{T}ᵢ_{^{PDG}}); the temperature prediction variable calculated in TPT (\hat{T}ᵢ_{^{TPT}}); and the temperature prediction variable calculated at the outlet (\hat{T}ᵢ_{^{out}}) are stored in vector format, wherein \hat{P}^{PDG}, \hat{P}^{TPT}, \hat{P}^{out}, \hat{T}^{PDG}, \hat{T}^{TPT}, \hat{T}^{out}∈ [symbol] ^{N}^{ₜₑₛₜₛ}.

12. Method, according to claim 1, wherein the step of determining upper and lower limits in the adjustment factors comprises defining:
the upper limit of the well pressure adjustment factor (φP^{well}) according to φP^{well}=max(φP^{well}, 0.8);
the lower limit of the well pressure adjustment factor (φP^{well}) according to φP^{well}=min(φP^{well}, 1.2);
the upper limit of the well temperature adjustment factor (φT^{well}), according to φT^{well}=max(φT^{well}, 0.8);
the lower limit of the well temperature adjustment factor (φT^{well}), according to φT^{well}=min(φT^{well}, 1.2);
the upper limit of the pipe pressure adjustment factor φP^{pipe} is set according to φP^{pipe}=max(φP^{pipe}, 0.8);
the lower limit of the pipe pressure adjustment factor (φP^{pipe}) according to φP^{pipe}=min(φP^{pipe}, 1.2);
the upper limit of the pipe temperature adjustment factor (φT^{pipe}) according to φT^{pipe}=max(φT^{pipe}, 0.8);
the lower limit of the pipe temperature adjustment factor (φT^{pipe}) according to φT^{pipe}=min(φT^{pipe}, 1.2).

13. Method, according to claim 1, wherein the step of performing a second multiphase flowability simulation comprises calculating and storing the values of:
pressure prediction variable calculated in PDG (\hat{P}ᵢ_{^{PDG}});
pressure prediction variable calculated in TPT [symbol] ᵢ_{^{TPT}});
pressure prediction variable calculated at the outlet (\hat{P}ᵢ_{^{out}});
temperature prediction variable calculated in PDG (\hat{T}ᵢ_{^{PDG}});
temperature prediction variable calculated in TPT (\hat{T}ᵢ_{^{TPT}});
temperature prediction variable calculated at the outlet (\hat{T}ᵢ_{^{out}}).

14. Method, according to claim 12, wherein the pressure prediction variable calculated in PDG (\hat{P}ᵢ_{^{PDG}}); the pressure prediction variable calculated in TPT (\hat{P}ᵢ_{^{TPT}}); the pressure prediction variable calculated at the outlet (\hat{P}ᵢ_{^{out}}); the temperature prediction variable calculated in PDG (\hat{T}ᵢ_{^{PDG}}); the temperature prediction variable calculated in TPT (\hat{T}ᵢ_{^{TPT}}); and the temperature prediction variable calculated at the outlet (\hat{T}ᵢ_{^{out}}) are stored in vector format, wherein \hat{P}^{PDG}, \hat{P}^{TPT}, \hat{P}^{out}, \hat{T}^{PDG}, \hat{T}^{TPT}, \hat{T}^{out}∈ [symbol] ^{N}^{ₜₑₛₜₛ}.

15. Method, according to claim 1, wherein the step of verifying whether the convergence criterion was met comprises verifying whether the method iteration termination criterion, set in the second step, was met; where if the method iteration termination criterion was not met, it is returned to the step of updating the well pressure adjustment factor (φP^{well}); the well temperature adjustment factor (φT^{well}); the pipe pressure adjustment factor (φP^{pipe}); and the pipe temperature adjustment factor (φT^{pipe}); or if the method iteration termination criterion was met, perform the step of obtaining optimized adjustment factors.

16. Computer-readable storage media, characterized by comprising, stored within itself, a set of computer-readable instructions, which when executed by a computer, execute the method as defined in claim 1.
